(19) United States
(12) Patent Application Publication
(10) Pub. No.: US 2025/0233010 A1
(43) Pub. Date: Jul. 17, 2025

(54) BASE, ELECTROSTATIC CHUCK DEVICE, AND MANUFACTURING METHOD OF BASE

(71) Applicant: SUMITOMO OSAKA CEMENT CO., LTD., Tokyo (JP)

(72) Inventors: Yuya Nakazawa, Tokyo (JP); Kenji HARADA, Tokyo (JP)

(73) Assignee: SUMITOMO OSAKA CEMENT CO., LTD., Tokyo (JP)

(21) Appl. No.: 19/019,298

(22) Filed: Jan. 13, 2025

(30) Foreign Application Priority Data
Jan. 17, 2024 (JP) 2024-005226

(51) Int. Cl. H01L 21/687; H01L 21/683

(52) U.S. Cl. CPC H01L 21/68757; H01L 21/6833

(57) ABSTRACT

A base includes a first member made of a metal matrix composite; a second member made of a metal matrix composite and overlapping with the first member; and an adhesive layer made of an organic material and adhering the first member and the second member to each other, in which the first member has a protruding strip portion on a side facing the second member, the adhesive layer is sandwiched between a top surface of the protruding strip portion and a surface of the second member facing the first member, and a space surrounded by a groove portion formed between adjacent protruding strip portions and the second member is a flow channel through which a refrigerant flows.

### CROSS-REFERENCE TO RELATED APPLICATIONS

This application claims the priority benefit of Japan Application No. 2024-005226, filed on Jan. 17, 2024. The entirety of the above-mentioned patent application is hereby incorporated by reference herein and made a part of this specification.

### BACKGROUND OF THE INVENTION

### Field of the Invention

The present invention relates to a base, an electrostatic chuck device, and a manufacturing method of a base.

### Description of Related Art

In the related art, in a semiconductor manufacturing process for manufacturing a semiconductor such as an IC, an LSI, or a VLSI, an electrostatic chuck device that electrostatically adsorbs a plate-shaped sample in a case of carrying out a plasma treatment on the plate-shaped sample such as a silicon wafer is used. With regard to the plate-shaped sample held by the electrostatic chuck device, the temperature distribution during the plasma treatment is uniformly controlled so that unevenness does not occur in the treatment state of the plate-shaped sample in the plasma treatment.

For example, an electrostatic chuck device having an electrostatic chuck member made of ceramics and a base made of a metal matrix composite (MMC) which is a composite material of a metal and ceramics has been proposed as the electrostatic chuck device (for example, see Japanese Laid-open Patent Publication No. H11-163109). In Japanese Laid-open Patent Publication No. H11-163109, an electrostatic chuck device is realized that easily transfers heat, making it possible to easily control the temperature distribution of a plate-shaped sample during the treatment to be uniform, due to the characteristics of the MMC constituting a base (base body).

In addition, a configuration is known in which a base of an electrostatic chuck device has a flow channel through which a refrigerant flows provided inside thereof (for example, see Japanese Laid-open Patent Publication No. 2020-167220). In the electrostatic chuck device having a base with such a configuration, it is possible to suitably cool a plate-shaped sample that is adsorbed to the electrostatic chuck member by flowing a refrigerant through the base.

### SUMMARY OF THE INVENTION

In recent years, with the diversification of semiconductor processes, the temperature of a plate-shaped sample during the treatment has been controlled within a wider temperature range than in the related art. In order to realize such temperature control, a base made of MMC and having a flow channel inside thereof has been studied as a novel base. In this regard, MMC is more difficult to process than a metal, so an improvement has been required.

The present invention has been made in view of such circumstances, and an object of the present invention is to provide a novel base made of MMC. Another object of the present invention is to provide a novel electrostatic chuck device having such a base. A further object of the present invention is to provide a manufacturing method of a base that enables easy manufacturing of such a base.

In order to achieve the above-mentioned objects, one aspect of the present invention includes the following aspects.
[1] A base including: a first member made of a metal matrix composite; a second member made of a metal matrix composite and overlapping with the first member; and an adhesive layer made of an organic material and adhering the first member and the second member to each other, in which the first member has a protruding strip portion on a side facing the second member,
the adhesive layer is sandwiched between a top surface of the protruding strip portion and a surface of the second member facing the first member, and
a space surrounded by a groove portion formed between adjacent protruding strip portions and the second member is a flow channel through which a refrigerant flows.
[2] The base according to [1], in which the adhesive layer may be formed only at a position in contact with the top surface of the protruding strip portion.
[3] The base according to [1] or [2], in which a thickness of the adhesive layer may be 30 μm or more and 300 μm or less.
[4] The base according to any one of [1] to [3], in which the adhesive layer may be positioned below an upper end of the flow channel.
[5] An electrostatic chuck device including: an electrostatic chuck member made of a ceramic material; the base according to any one of [1] to [4]; and a bonding layer bonding the electrostatic chuck member to the base, in which the electrostatic chuck member contains 50% by volume or more of aluminum oxide in a case where a total amount of the electrostatic chuck member is taken as 100% by volume.
[6] The electrostatic chuck device according to [5], in which the bonding layer may contain a resin material and a thermally conductive filler, and a content rate of the thermally conductive filler in the bonding layer may be 50% by mass or more and 80% by mass or less.
[7] A manufacturing method of a base including: a step of forming a precursor in which a groove portion is formed on at least one of a pair of green sheets; a step of infiltrating a metal into a sintered body obtained by calcining the precursor to manufacture a first member and a second member, the first member being made of a metal matrix composite and the second member being made of a metal matrix composite and overlapping with the first member; and a step of disposing the first member and the second member to face each other with the groove portion facing inward and adhering the first member and the second member to each other with an organic sheet adhesive.

### Advantageous Effects of Invention

According to the present invention, it is possible to provide a novel base made of MMC. In addition, it is possible to provide a novel electrostatic chuck device having such a base. Further, it is possible to provide a manufacturing method of a base that enables easy manufacturing of such a base.

### BRIEF DESCRIPTION OF THE DRAWING

FIG. 1 is a schematic cross-sectional view showing an electrostatic chuck device 1A.

FIG. 2 is a process diagram showing an example of a manufacturing method of a base 3A.

FIG. 3 is a process diagram showing an example of a manufacturing method of a base 3A.

FIG. 4 is a process diagram showing an example of a manufacturing method of a base 3A.

FIG. 5 is an explanatory view of a base according to a modification example.

FIG. 6 is an explanatory view of a base according to a modification example.

### DETAILED DESCRIPTION OF THE INVENTION

### First Embodiment

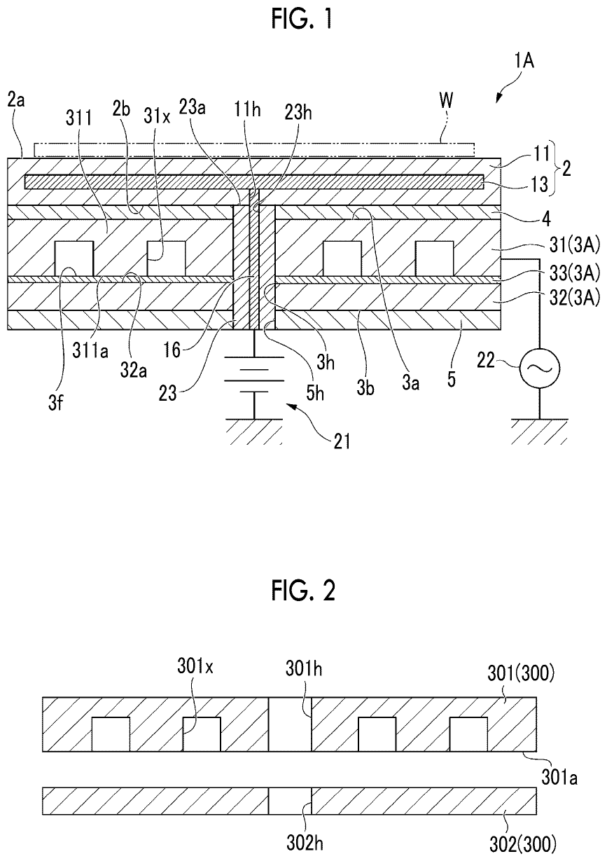

Hereinafter, a base, a manufacturing method of a base, and an electrostatic chuck device according to the present embodiment will be described with reference to FIG. 1. In all of the drawings below, dimensions, ratios, and the like of the components may be appropriately different from the actual ones in order to easily understand the drawings.

### Base and Electrostatic Chuck Device

FIG. 1 is a schematic cross-sectional view showing an electrostatic chuck device 1A. The electrostatic chuck device 1A includes an electrostatic chuck member 2, a base 3A, a bonding layer 4, a supporting plate 5, an insulator (insertion component) 23, and a power supply terminal 16. The electrostatic chuck member 2 and the base 3A are stacked with each other through the bonding layer 4.

In the present specification, the direction in which the electrostatic chuck member 2 and the base 3A are stacked is referred to as a stacking direction. Further, the side of the base 3A on which the electrostatic chuck member 2 is disposed is referred to as one side in the stacking direction, and the opposite side is referred to as an other side in the stacking direction. In addition, in the following description, each part of the electrostatic chuck device 1A will be described with the vertical direction being the stacking direction. In this regard, the vertical direction described herein is merely a direction used for the sake of simplicity of explanation, and does not limit the position of the electrostatic chuck device 1A during use. The upper side corresponds to one side in the stacking direction and the lower side corresponds to the other side in the stacking direction.

### Electrostatic Chuck Member

The electrostatic chuck member 2 has a dielectric substrate 11 and an adsorption electrode 13 located inside the dielectric substrate 11. A placement surface 2a for adsorbing a wafer W is provided on the upper surface of the electrostatic chuck member 2. A focus ring surrounding the wafer W may be disposed outside the placement surface 2a of the electrostatic chuck member 2.

The dielectric substrate 11 is made of a composite sintered body having a sufficient mechanical strength and durability against corrosive gases and plasmas thereof. Ceramics having mechanical strength and durability against corrosive gases and plasmas thereof are suitably used as the dielectric material constituting the dielectric substrate 11.

The ceramic constituting the dielectric substrate 11 contains aluminum oxide (Al₂O₃) as a main component. The term “main component” refers to a component that occupies 50% by volume or more of the total components. For example, an aluminum oxide (Al₂O₃) sintered body, an aluminum oxide (Al₂O₃)-silicon carbide (SiC) composite sintered body, or the like is suitably used. In particular, from the viewpoint of dielectric characteristics at a high temperature, high corrosion resistance, plasma resistance, and heat resistance, it is preferable that the material constituting the dielectric substrate 11 is an Al₂O₃—SiC composite sintered body.

The dielectric substrate 11 has a circular plate shape in a plan view. The dielectric substrate 11 has the placement surface 2a on which the wafer W is placed, and a back surface 2b facing the opposite side of the placement surface 2a. For example, a plurality of protruding portions (not shown) may be formed at predetermined intervals on the placement surface 2a. In this case, the placement surface 2a supports the wafer W at the tip portions of the plurality of protruding portions.

The adsorption electrode 13 is disposed inside the dielectric substrate 11. The adsorption electrode 13 extends in a plate shape along the placement surface 2a of the dielectric substrate 11. In a case where a voltage is applied, the adsorption electrode 13 generates an electrostatic adsorption force that holds the wafer W in the placement surface 2a of the dielectric substrate 11. The power supply terminal 16 for applying a direct current voltage to the adsorption electrode 13 is connected to the adsorption electrode 13.

The adsorption electrode 13 is made of a composite of an insulating material and a conductive material. The insulating material contained in the adsorption electrode 13 is not particularly limited and is preferably, for example, at least one selected from the group consisting of aluminum oxide (Al₂O₃), aluminum nitride (AlN), silicon nitride (Si₃N₄), yttrium (III) oxide (Y₂O₃), yttrium aluminum garnet (YAG), and SmAlO₃. The conductive material contained in the adsorption electrode 13 is preferably at least one selected from the group consisting of molybdenum carbide (MO₂C), molybdenum (Mo), tungsten carbide (WC), tungsten (W), tantalum carbide (TaC), tantalum (Ta), silicon carbide (SiC), carbon black, carbon nanotubes, and carbon nanofibers.

The electrostatic chuck member 2 preferably has a thickness of 0.5 mm or more and 5 mm or less. In a case where the thickness of the electrostatic chuck member 2 is 0.5 mm or more, the dielectric withstanding voltage of the electrostatic chuck member 2 is increased. In addition, in a case where the thickness of the electrostatic chuck member 2 is 5 mm or less, the heat capacity of the electrostatic chuck member 2 is small, so the temperature of the plate-shaped sample, which is an object to be treated, is easily kept uniform during the plasma treatment.

### Base

The electrostatic chuck member 2 is supported from below on the base 3A. The base 3A has a support surface 3a facing upward and a lower surface 3b facing downward. The support surface 3a faces the back surface 2b of the dielectric substrate 11 in a vertical direction through the bonding layer 4. The base 3A supports the electrostatic chuck member 2 on the support surface 3a.

A flow channel 3f that allows a refrigerant to flow and circulate is provided inside the base 3A. Water, He gas, N₂ gas, or the like is employed as the refrigerant flowing through the flow channel 3f. The flow channel 3f extends along the support surface 3a. The refrigerant in the flow channel 3f cools the entire base 3A and cools the electrostatic chuck member 2 through the support surface 3a.

The base 3A is a disk-shaped member in a plan view and is made of a material having a thermal conductivity of 140 W/m·K or higher. In the present specification, the term “plan view” refers to a field of view seen from the thickness direction of the electrostatic chuck member 2.

The base 3A has a first member 31, a second member 32, and an adhesive layer 33. The first member 31 and the second member 32 are adhered to each other through the adhesive layer 33. That is, the first member 31 and the second member 32 are integrated through the adhesive layer 33 by the adhesive layer 33 being adhered to both the first member 31 and the second member 32.

### First Member and Second Member

The first member 31 is a disk-shaped member in a plan view and has a protruding strip portion 311 on a side facing the second member 32. A groove portion 31x is formed between the adjacent protruding strip portions 311.

The second member 32 is a disk-shaped member in a plan view. The contour of the second member 32 overlaps with (is consistent with) the contour of the first member 31 in a plan view.

The space surrounded by the groove portion 31x and the second member 32 corresponds to the flow channel 3f.

The first member 31 and the second member 32 can be made of a known metal matrix composite (hereinafter, referred to as MMC). The MMC can be adjusted by a known method in which a porous ceramic base material is adjusted and then a metal is introduced into the micropores of the ceramic base material (metal infiltration method or forging method).

The material for forming the first member 31 and the material for forming the second member 32 may be different from each other, but are preferably the same material. The “same material” means that the materials of constituting the MMC, i.e. the ceramic base material and the metal introduced into the micropores, are both the same. In a case where the material for forming the first member 31 and the material for forming the second member 32 are the same material, it is more preferable that the ratio of the metal introduced into the ceramic base material is also the same.

More specifically, the MMC, which is the material of the first member 31 and the second member 32, preferably contains SiC as a material. Specifically, in a case where the total amount of the first member 31 and the second member 32 is taken as 100% by volume, the MMC contains SiC in an amount of 75% by volume or more and less than 100% by volume, and preferably contains SiC in an amount of 75% by volume or more and 99% by volume or less.

The MMC contains, as the metal to be introduced into the micropores, one or more elements selected from the group consisting of aluminum (Al), silicon (Si), and magnesium (Mg). The inclusion of these elements in SiC improves the thermal conductivity of the base 3A, facilitating heat dissipation through base 3A. In the MMC containing SiC in an amount of 75% by volume or more, the thermal expansion coefficient can be controlled in a range of 2.8×10⁻⁶/K to 6.8×10⁻⁶/K by adjusting a counterpart material to be contained in the material.

The absolute value of the difference in thermal expansion coefficient between the MMC and the ceramic material which is the material of the electrostatic chuck member 2 is 10 ppm/K or lower and preferably 7.0 ppm/K or lower. Since the material of the base 3A and the material of the electrostatic chuck member 2 have the above-mentioned relationship, it is easy to suppress internal stress due to thermal deformation during heating.

It is preferable that the MMC is a material containing SiC in an amount of 75% by volume or more and 99% by volume or less and containing Al, Si, or Mg in an amount of 1% by volume or more and 25% by volume or less in a case where the total amount of MMC is taken as 100% by volume. The base 3A formed of the MMC having such a composition as the material has a thermal expansion coefficient that is very close to that of the Al₂O₃—SiC that constitutes the electrostatic chuck member 2, and the difference in the amount of thermal expansion between the base 3A and the electrostatic chuck member 2 during heating is small.

For example, Mg—SiC (7.0 ppm/K), Al—SiC (6.8 ppm/K), or Si—SiC (2.8 ppm/K) can be used as the MMC. The amount of metal contained in each MMC can be appropriately adjusted within the above-mentioned range of the content rate depending on the desired thermal expansion coefficient.

### Adhesive Layer

The adhesive layer 33 is made of an organic material. The adhesive layer 33 is provided on the entire surface of one surface 32a of the second member 32 and is sandwiched between a top surface 311a of the protruding strip portion 311 and a surface (one surface 32a) of the second member 32 facing the first member 31.

Examples of the material of the adhesive layer 33 include a silicone-based resin, an acrylic resin, an epoxy-based resin, and a polyimide-based resin.

The thickness of the adhesive layer 33 is preferably 30 μm or more and 300 μm or less, more preferably 75 μm or more and 150 μm or less, and still more preferably 75 μm or more and 120 μm or less.

In addition, in FIG. 1, the adhesive layer 33 is located below the upper end of the flow channel 3f. In this configuration, since the adhesive layer 33 is not interposed between the placement surface 2a and the flow channel 3f, heat transfer is not likely to be hindered by the adhesive layer 33 formed of an organic material.

The adhesive layer 33 may be formed by applying a paste-like adhesive onto one surface of the second member 32 and curing the paste-like adhesive, or may be formed by disposing a sheet-like adhesive between the first member 31 and the second member 32 and curing the sheet-like adhesive.

In a case where the first member 31 and the second member 32 are formed of a metal material, Si bonding or silver brazing is considered as a method of joining and integrating both the first member 31 and the second member 32. However, as a result of studies conducted by the present inventors, it was found that the following problems unexpectedly occur in a case where these methods are used in a case of integrating members made of MMC.

First, in a case of Si bonding, in a case where the first member 31 and the second member 32 made of Si—SiC (MMC) were bonded to each other by Si bonding, a portion where Si contained in the MMC was ejected into the inside of the formed flow channel 3f was confirmed. This is considered to be because the metal that had infiltrated into the MMC was melted by heating during the Si bonding. In a case where Si is ejected into the flow channel 3f, there is a risk that the flow channel 3f may be blocked. In addition, even in a case where the flow channel 3f is not blocked, the cross-sectional area of the flow channel 3f is reduced, resulting in a pressure loss, which leads to a deterioration in performance of the base 3A.

The above-mentioned problem is not limited to a case where the MMC is Si—SiC, and the same problem can also occur in a case where the MMC is Al—SiC or Mg—SiC, in which Al or Mg, which has a lower melting point than Si, has infiltrated therein.

In addition, in a case of silver brazing, Si contained in the MMC diffuses from the bonding surface into the silver brazing material, forming an Ag—Si alloy. As a result, there is a concern that the bonding strength between the first member 31 and the second member 32 may be reduced, which may lead to a deterioration in reliability of the base 3A.

The above-mentioned problem is not limited to a case where the MMC is Si—SiC, and may occur even in a case where the MMC is Al—SiC or Mg—SiC.

Based on the above findings, in the base 3A of the present embodiment, the first member 31 and the second member 32 are adhered and integrated with each other by the adhesive layer 33 made of an organic material which is used as a forming material. In a case where the adhesive is cured and then even in a case where heating is required, the reaction temperature (for example, 130° C.) of the adhesive is lower than the heating temperature during Si bonding, making it possible to suppress the ejection of metal from within the MMC. In addition, the metal in the MMC does not diffuse into the adhesive layer 33 made of an organic material.

The manufacturing method of such a base will be described later.

It is preferable that the surface of the base 3A is covered with a metal film. For example, an Al sprayed film can be adopted as the metal film. The film thickness of the metal film can be, for example, 100 μm or more and 300 μm or less. This makes it possible to use the base 3A as an internal electrode for generating plasma. The base 3A is connected to an external high-frequency power source 22 through a matching device (not shown).

The base 3A is provided with a hole portion 3h. The hole portion 3h extends along a vertical direction. The hole portion 3h passes through the base 3A in a vertical direction and is open to the support surface 3a and the lower surface 3b of the base 3A, respectively. The hole portion 3h has, for example, a circular shape in a plan view. An insulator 23, which will be described later, is inserted into the hole portion 3h.

### Bonding Layer

The bonding layer 4 is interposed between the electrostatic chuck member 2 and the base 3A and bonds the electrostatic chuck member 2 to the base 3A. The bonding layer 4 is preferably a layer made of a mixture containing a resin material and a thermally conductive filler (hereinafter, simply referred to as a filler).

### Bonding Layer

The bonding layer 4 is sandwiched between the electrostatic chuck member 2 and the base 3A and adheres the electrostatic chuck member 2 and the base 3A to each other. The bonding layer 4 contains a resin material and a thermally conductive filler (hereinafter, simply referred to as a filler).

The bonding layer 4 containing the resin material is relatively more easily deformed than the electrostatic chuck member 2 and the base 3A. Therefore, as compared with a bonding layer formed by brazing, the bonding layer 4 is more likely to be deformed in response to the expansion or contraction of the electrostatic chuck member 2 and the base 3A due to a change in temperature. In addition, for example, even in a case where there is a difference between the amount of thermal expansion of the electrostatic chuck member 2 and the amount of thermal expansion of the base 3A, the internal stress caused by the difference in the amount of thermal expansion can be suppressed by deformation of the bonding layer 4.

The resin is not particularly limited as long as it is not susceptible to cohesive failure due to thermal stress, and examples thereof include a silicone resin, an acrylic resin, an epoxy resin, a phenol resin, a polyurethane resin, an unsaturated polyester resin, and the like. Among these resins, a silicone resin is preferable from the viewpoint of a high degree of expansion and contraction and being less susceptible to cohesive failure due to a change in thermal stress.

The filler has a function of improving the thermal conductivity of the bonding layer 4 in a thickness direction. For this function, the filler can be, for example, one or more selected from the group consisting of an inorganic oxide, an inorganic nitride, and an inorganic oxynitride. For example, the filler preferably contains surface-coated aluminum nitride (AlN) particles in which a coating layer consisting of silicon oxide (SiO₂) or aluminum oxide (Al₂O₃) is formed on the surface of the aluminum nitride (AlN) particles.

The content rate of the filler in the bonding layer 4 is 50% by mass or more and 80% by mass or less. The content rate of the filler is preferably 55% by mass or more and more preferably 60% by mass or more. In addition, the content rate of the filler is preferably 75% by mass or less and more preferably 70% by mass or less. The upper limit value and the lower limit value of the content rate of the filler can be optionally combined.

In a case where the content rate of the filler is equal to or higher than the lower limit value, it is possible to impart sufficient thermally conductive properties to the bonding layer 4 and to promote the transfer of heat from the electrostatic chuck member 2 to the base 3A. In a case where the content rate of the filler is equal to or lower than the upper limit value, the electrostatic chuck member 2 and the base 3A are likely to be deformed in response to the expansion or contraction due to a change in temperature.

In a case where a bonding layer containing a resin material is adopted, Al is adopted as a material of the base in a well-known electrostatic chuck device. The base made of Al has a larger thermal expansion coefficient and is more significantly deformed in a case of being heated, as compared with an electrostatic chuck member made of ceramics. Therefore, in a case where the electrostatic chuck member and the base are thermally expanded in a plasma process, there is a risk that the difference in the amount of thermal expansion between the electrostatic chuck member and the base is large, and the bonding layer containing a resin material is broken. However, since the base 3A of the present embodiment is made of MMC, the difference in the amount of thermal expansion with the electrostatic chuck member 2 can be reduced, and the breakage of the bonding layer can be suppressed.

Further, in the electrostatic chuck device 1A of the present embodiment, by adopting the base 3A made of MMC, the amount of deformation required for the bonding layer to absorb thermal expansion of the electrostatic chuck member 2 and the base 3A may be smaller than in the electrostatic chuck device that adopts the base made of Al. Therefore, the amount of the filler contained in the bonding layer can be increased to 50% by mass or more and 80% by mass or less, and the thermal conductivity of the bonding layer can be further improved, as compared with the electrostatic chuck device that adopts the base made of Al.

In a case where the amount of the filler contained in the bonding layer 4 is large, the filler is likely to aggregate in a case where the resin material (adhesive) before curing and the filler are kneaded, making it difficult to disperse the filler in the resin. In order to facilitate the dispersion of the filler during kneading, the filler is preferably spherical rather than plate-like or fibrous.

In addition, in order to facilitate the dispersion of the filler during kneading, the filler preferably has a bimodal particle diameter distribution.

The shape of the filler and the bimodal particle diameter distribution of the filler can be confirmed by the following method.

First, the electrostatic chuck member 2 or the base 3A is peeled off from the electrostatic chuck device 1A to expose the bonding layer 4, and the surface of the exposed bonding layer 4 is processed to be flat by ion milling. An SEM image of the obtained cross section is captured, and the particle diameter of each of a plurality of fillers included in the obtained image is measured by image analysis. The particle diameter of the filler can be determined by analysis with image analysis software attached to SEM.

The magnification of the SEM image is not limited as long as the particle diameter of the filler contained in the bonding layer 4 can be measured, but may be a magnification at which at least 200 fillers are included in one field of view of the SEM image. The magnification of the SEM image may be, for example, 100 times to 5000 times.

The shape (plate-like, fibrous, or spherical) of the filler included in the SEM image is confirmed from the obtained measured value.

In addition, the particle diameter distribution of the filler included in the SEM image is obtained from the obtained measured value, and it is confirmed whether or not the particle diameter distribution is a bimodal particle diameter distribution.

In the present embodiment, the filler being “bimodal” means that there are two or more peaks, preferably two peaks showing a maximum in the particle diameter distribution obtained by the above-mentioned method. Whether the filler used as the material of the electrostatic chuck device 1A has a bimodal particle diameter distribution may be determined by measuring the particle diameter distribution of the filler by a known laser diffraction scattering method, in addition to the above-mentioned method.

The average particle diameter of the thermally conductive filler contained in the bonding layer 4 is preferably ½ or less of the thickness of the bonding layer 4, and more preferably 1/2000 or more and ½ or less of the thickness of the bonding layer 4. In a case where the average particle diameter of the thermally conductive filler is 1 μm or more and 100 μm or less, the thickness of the bonding layer 4 is preferably 2 μm or more and 200 μm or less. Setting the thickness of the bonding layer 4 in this manner makes it easier to form the bonding layer 4 containing the filler with a uniform thickness, thereby reducing cooling unevenness (improving temperature uniformity).

The average particle diameter of the filler can be determined by image analysis from the above-mentioned SEM image.

Such a bonding layer 4 preferably has a thermal conductivity of 0.3 W/m·K or higher and more preferably has a thermal conductivity of 1.0 W/m·K or higher. In a case where the bonding layer 4 has such a thermal conductivity, heat can be appropriately transferred from the electrostatic chuck member 2 to the base 3A, thereby allowing the entire device to be appropriately cooled.

In addition, the elastic modulus of the bonding layer 4 at 25° C. is preferably 10000 MPa or lower, and more preferably 1000 MPa or lower. In a case where the electrostatic chuck device 1A is used in a plasma process and heating and cooling are repeated, the bonding layer 4 may be peeled off at the interface due to internal stress caused by the difference in thermal expansion between the electrostatic chuck member 2 and the base 3A. On the other hand, in a case where the bonding layer 4 has the above-mentioned elastic modulus, the bonding layer 4 can relieve the above-mentioned internal stress and suppress the peeling.

The thermal conductivity and the elastic modulus can be controlled by adjusting the addition amount of the filler. Tables 1 and 2 below show the thermal conductivity and elastic modulus in a case where each filler was added to a silicone resin, and the presence or absence of peeling after adhesion of the base made of MMC (SiC: 82% by volume, Si: 18% by volume)/ceramics material (Al₂O₃—SiC).

TABLE 1

| | | | | Presence or |
|---|---|---|---|---|
| | | | | absence of |
| Amount of | Amount | | | peeling after |
| alumina | of resin | Thermal | Elastic | adhesion of |
| added | added | conductivity | modulus@25° C. | MMC/ceramics |
| [vol %] | [vol %] | [w/m · k] | [MPa] | material |
| 0 | 100 | 0.2 | 30 | ∘ |
| 40 | 60 | 0.8 | 42 | ∘ |
| 50 | 50 | 1.3 | 68 | ∘ |
| 60 | 40 | 2.0 | 160 | ∘ |
| 70 | 30 | 3.5 | 350 | ∘ |
| 80 | 20 | 5.5 | 810 | ∘ |
| 90 | 10 | 8.0 | 1670 | x |

TABLE 2

| | | | | Presence or |
|---|---|---|---|---|
| Amount of | | | | adhesion of |
| aluminum | Amount | | | peeling after |
| nitride | of resin | Thermal | Elastic | absence of |
| added | added | conductivity | modulus@25° C. | MMC/ceramics |
| [vol %] | [vol %] | [w/m · k] | [MPa] | material |
| 0 | 100 | 0.2 | 30 | ∘ |
| 40 | 60 | 0.9 | 60 | ∘ |
| 50 | 50 | 1.4 | 120 | ∘ |
| 60 | 40 | 2.5 | 200 | ∘ |
| 70 | 30 | 4.5 | 450 | ∘ |
| 80 | 20 | 7.0 | 990 | ∘ |
| 90 | 10 | 10.0 | 1800 | x |

The bonding layer 4 may be formed by sandwiching a liquid adhesive between the electrostatic chuck member 2 and the base 3A and then curing the adhesive, or may be formed by sandwiching a sheet-like or film-like adhesive between the electrostatic chuck member 2 and the base 3A.

In a case where the material of the bonding layer 4 is a liquid adhesive, the viscosity of the adhesive is preferably 500 Pa·s or lower.

As described above, in a case where the amount of the filler contained in the bonding layer 4 increases, the adhesive force between the bonding layer 4 and the base 3A is likely to decrease. For this reason, it is preferable that a primer layer is formed on the surface of the base 3A that comes into contact with the bonding layer 4.

The primer layer is made of an organosilicon compound having a functional group that reacts with the resin material (adhesive) which is a material of the bonding layer 4, and an alkoxy group. Examples of the functional group include an epoxy group, a vinyl group, a methacryloyl group, and a mercapto group. In addition, the above-mentioned organosilicon compound has one or more alkoxy groups. Furthermore, the organosilicon compound may be a monomolecular compound or a polymer. As such an organosilicon compound, a compound known as a material for the primer layer can be used.

In a case where such an organosilicon compound is applied to the surface of the base 3A, the alkoxy group contained in the organosilicon compound reacts with the surface of the base 3A to form a bond. In addition, the functional group contained in the organosilicon compound reacts with the adhesive to form a bond. As a result, in a case where the primer layer is formed, a higher adhesive force is generated between the bonding layer 4 and the base 3A, as compared with a case where the primer layer is not present.

In addition, the bonding layer 4 may be a layer made of a metal material.

The bonding layer 4 is made of an alloy containing 50% by volume or more of Al or Ag and 0.02% by volume or more and 40% by volume or less of at least one metal selected from the group consisting of Ti, Zr, and Hf, in a case where the total amount of bonding layer 4 is taken as 100% by volume. Since the bonding layer 4 contains at least one metal selected from the group consisting of Ti, Zr, and Hf, in a case where the electrostatic chuck member 2 and the base 3A are bonded to each other, the molten alloy formed by melting the material of the bonding layer 4 easily spreads over the surface of the ceramic (electrostatic chuck member 2), facilitating bonding. In addition, since the bonding layer 4 contains the above-mentioned metal, the above-mentioned metal and the ceramic (electrostatic chuck member 2) are likely to be closely attached to each other, so the occurrence of voids at the interface can be suppressed and strong bonding can be achieved.

The thickness of the bonding layer 4 is preferably 0.005 mm or more and 0.5 mm or less.

In a case of manufacturing the electrostatic chuck device 1A, the material of the bonding layer 4 used may be a metal foil or a metal paste in which a binder is added to a metal powder. These materials are disposed between the electrostatic chuck member 2 and the base 3A, and heated to a temperature equal to or higher than a melting point of the metal material that forms the bonding layer, and the molten metal material is spread between the electrostatic chuck member 2 and the base 3A, whereby the bonding layer 4 can be formed.

### Supporting Plate

The supporting plate 5 supports the base 3A from the lower surface 3b of the base 3A. In addition, the supporting plate 5 has a hole 5h into which the insulator 23 is inserted. The supporting plate 5 is made of a material having a higher Young's modulus than the material of the base 3A. For example, any of metal, MMC, and ceramics can be used as the material of the supporting plate 5. Above all, it is preferable to use a ceramic plate such as Al₂O₃ or the like having a higher Young's modulus than the base 3A as the supporting plate 5.

The ceramic material used for the supporting plate 5 is preferably the same as the material used for the electrostatic chuck member 2. Specific examples of the ceramics include aluminum oxide and aluminum nitride. By using the same material for the supporting plate 5 and the electrostatic chuck member 2, the difference in thermal expansion coefficient between the supporting plate 5 and the electrostatic chuck member 2 can be reduced, and warping of the electrostatic chuck device 1A is suppressed.

### Insulator

The insulator 23 is inserted into the hole portion 3h and the hole 5h and assembled to the base 3A. That is, the insulator 23 functions as an insertion component that is inserted into the hole portion 3h and the hole 5h. The insulator 23 has a tubular shape extending in a vertical direction (stacking direction). The power supply terminal 16 is disposed in a through-hole 23h of the insulator 23.

The outer peripheral surface of the insulator 23 is bonded to the inner surfaces of the hole portion 3h and the hole 5h using a bonding means such as adhesion. The insulator 23 insulates the metallic base 3A from the power supply terminal 16.

The insulator 23 is made of, for example, ceramic. That is, the insulator 23 is composed of an insulating member. This makes it possible for the insulator 23 to suppress a gas introduction hole from being a starting point of abnormal discharge. The insulator 23 has durability against plasma. As the ceramics constituting the insulator 23, ceramics containing one or two or more selected from AlN, Al₂O₃, Si₃N₄, zirconium oxide (ZrO₂), sialon, boron nitride (BN), and SiC can be adopted.

An end surface (hereinafter, an upper end surface 23a) of the insulator 23 on the upper side (one side in a stacking direction) is in contact with the electrostatic chuck member 2 or is disposed adjacent to the electrostatic chuck member 2 with an insulating adhesive interposed therebetween.

### Power Supply Terminal

The power supply terminal 16 extends from the adsorption electrode 13 toward the lower side. The power supply terminal 16 is connected to an external electric power source 21. The electric power source 21 applies a voltage to the adsorption electrode 13. The number, shape, and the like of the power supply terminals 16 are determined depending on the type of the adsorption electrode 13, that is, whether the adsorption electrode 13 is a monopolar type or a bipolar type.

The power supply terminal 16 is inserted through a hole 11h provided in the lower part of the dielectric substrate 11, which reaches the adsorption electrode 13, and through the through-hole 23h of the insulator 23.

The hole 11h and the through-hole 23h are each circular in a case of being viewed from the stacking direction and are in communication with each other. The inner diameters of the hole 11h and the through-hole 23h are slightly larger than the outer diameter of the power supply terminal 16.

According to the base having the above-mentioned configuration, it is possible to obtain a novel base made of MMC.

In addition, according to the electrostatic chuck device having the above-mentioned configuration, it is possible to provide a novel electrostatic chuck device using a base made of MMC.

### Manufacturing Method of Base

FIGS. 2 to 4 are process diagrams showing an example of a manufacturing method of the base 3A, and are cross-sectional views in the same field of view as that of FIG. 1.

First, SiC powder, a binder, a plasticizer, and the like are mixed in a predetermined ratio to form a slurry, which is then applied and dried to form a pair of green sheets of SiC. The green sheet to be used may be a commercially available product.

Next, as shown in FIG. 2, a pair of green sheets 300 are processed to form a first precursor 301 which is a precursor of the first member and a second precursor 302 which is a precursor of the second member (a step of forming a precursor). Specifically, at least one of the pair of green sheets 300 is processed to form a groove portion 301x on one surface 301a. In addition, a through-hole 301h penetrating in the thickness direction of the green sheet 300 is formed to obtain the first precursor 301.

In addition, a through-hole 302h penetrating in a thickness direction is formed in an other green sheet 300 to obtain the second precursor 302.

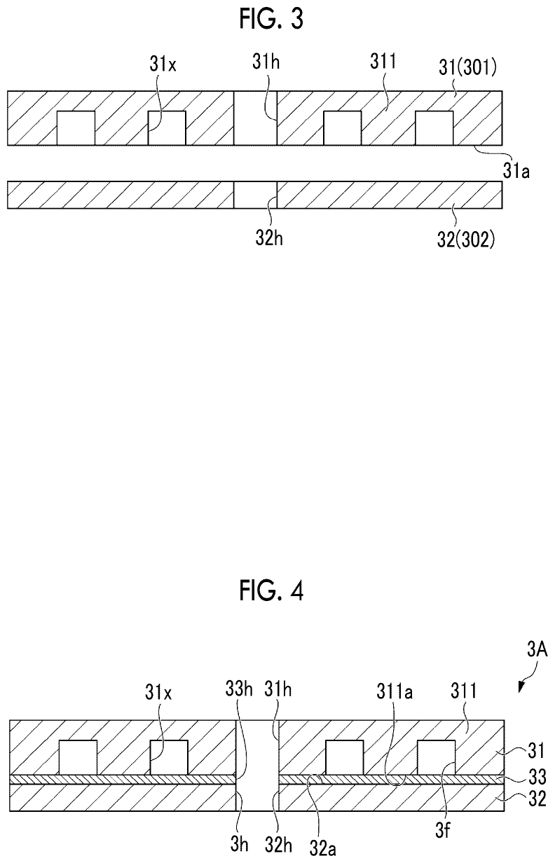

Next, as shown in FIG. 3, the first member 31 is manufactured from the first precursor 301, and the second member 32 is manufactured from the second precursor 302 (a step of manufacturing a first member and a second member).

Specifically, the first precursor 301 is calcined, and infiltrated with a metal (Si, Al, or Mg) by, for example, a known metal infiltration method, to manufacture the first member 31. The shape of the groove portion 301x of the first precursor 301 is maintained, and the groove portion 301x becomes the groove portion 31x of the first member 31. Similarly, the through-hole 301h becomes a through-hole 31h of the first member 31. In the first member 31, the protruding strip portion 311 that protrudes relatively with respect to the groove portion 31x is formed.

Similarly, the second precursor 302 is calcined, and infiltrated with a metal by a known metal infiltration method to manufacture the second member 32. The through-hole 302h of the second precursor 302 becomes a through-hole 32h of the second member 32.

Next, as shown in FIG. 4, the first member 31 and the second member 32 are adhered to each other (adhering step). Specifically, the first member 31 and the second member 32 are disposed to face each other with the groove portion 31x of the first member 31 facing inward and are adhered to each other with an adhesive. As a result, the top surface 311a of the protruding strip portion 311 and the one surface 32a (surface facing the first member 31) of the second member 32 are adhered to each other. The adhesive is cured to form the adhesive layer 33. The adhesive layer 33 is sandwiched between the top surface 311a and the one surface 32a.

A paste-like or gel-like adhesive having flowability may be used as the adhesive, or a sheet-like adhesive may be used as the adhesive. It is preferable to use a sheet-like adhesive since it is easy to suppress the adhesive from spilling out and is easy to process.

The space surrounded by the groove portion 31x and the one surface 32a of the second member 32 (the adhesive layer 33 formed on the one surface 32a) becomes the flow channel 3f.

The adhesive layer 33 has a through-hole 33h formed therein, which overlaps with the through-hole 31h of the first member 31 and the through-hole 32h of the second member 32 in plan view. By curing the adhesive, the hole portion 3h is obtained in which the through-hole 31h, the through-hole 32h, and the through-hole 33h communicate with each other.

According to the manufacturing method of the base having the above-mentioned configuration, since a green sheet is used as a starting raw material, it is possible to easily manufacture a base made of MMC, which is difficult to process. In addition, the first member 31 and the second member 32 can be suitably integrated to manufacture the base 3A by using an organic material (organic adhesive) for the adhesion between both the first member 31 and the second member 32.

### Modification Examples

In the present embodiment, the adhesive layer 33 is provided on the entire surface of the one surface 32a of the second member 32 in the base 3A, but the configuration is not limited thereto.

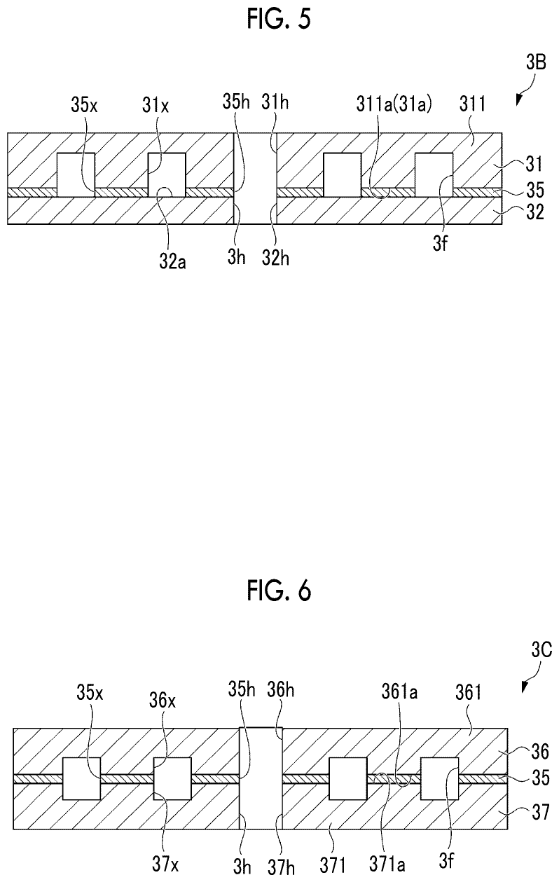

FIGS. 5 and 6 are explanatory views of bases according to modification examples and are views corresponding to FIG. 4.

A base 3B shown in FIG. 5 has a first member 31, a second member 32, and an adhesive layer 35. The adhesive layer 35 has a through-hole 35h overlapping with the hole portion 3h and has a through-hole 35x overlapping with the groove portion 31x of the first member 31. That is, in the base 3B, the adhesive layer 35 is formed only at a position in contact with the top surface 311a of the protruding strip portion 311.

In such a base 3B, the space surrounded by the groove portion 31x, the one surface 32a of the second member 32, and the through-hole 35x forms the flow channel 3f.

A base 3C shown in FIG. 6 has a first member 36, a second member 37, and an adhesive layer 35.

The first member 36 is a disk-shaped member in a plan view. The first member 36 has a protruding strip portion 361 on a side facing the second member 37 and has a through-hole 36h that penetrates the first member 36 in a thickness direction. In the first member 36, a groove portion 36x is formed between adjacent protruding strip portions 361.

The second member 37 is a disk-shaped member in a plan view. The contour of the second member 37 overlaps with the contour of the first member 36 in a plan view. The second member 37 has a protruding strip portion 371 on a side facing the first member 36 and has a through-hole 37h that penetrates the second member 37 in a thickness direction. In the second member 37, a groove portion 37x is formed between adjacent protruding strip portions 371.

Such first member 36 and second member 37 can be manufactured in a manner similar to the method of manufacturing the first member 31 described above.

In the base 3C, the adhesive layer 35 is formed only at a position in contact with a top surface 361a of the protruding strip portion 361. As a result, the adhesive layer 35 is sandwiched between the top surface 361a of the protruding strip portion 361 and the top surface 371a of the protruding strip portion 371.

In the base 3C, the space surrounded by the groove portion 36x, the groove portion 37x, and the through-hole 35x forms the flow channel 3f. In addition, the through-hole 36h, the through-hole 37h, and the through-hole 35h communicate with each other to form the hole portion 3h.

The adhesive layer 35 of the base 3B and the base 3C can be formed in a manner similar to that for the adhesive layer 33.

Such base 3B or base 3C can be used as a base included in the electrostatic chuck device by replacing the base 3A of the electrostatic chuck device 1A shown in FIG. 1.

The base 3B and the base 3C are novel bases made of MMC. In addition, the base 3B and the base 3C have a smaller area of the adhesive layer exposed to the inner surface of the flow channel 3f, as compared with the base 3A. Therefore, in electrostatic chuck devices having the base 3B and the base 3C, heat transfer is less likely to be hindered by the adhesive layer, and heat transferred from the placement surface can be suitably removed, making it possible to achieve a uniform temperature distribution on the placement surface.

Although the preferred embodiments of the present invention have been described above with reference to the accompanying drawings, the present invention is not limited to these embodiments. The various shapes, combinations, and the like of the constituent members shown in the above examples are merely examples, and various modifications can be made based on design requirements and the like without departing from the scope and spirit of the present invention.

What is claimed is:

1. A base comprising:
a first member made of a metal matrix composite;
a second member made of a metal matrix composite and overlapping with the first member; and
an adhesive layer made of an organic material and adhering the first member and the second member to each other,
wherein the first member has a protruding strip portion on a side facing the second member,
the adhesive layer is sandwiched between a top surface of the protruding strip portion and a surface of the second member facing the first member, and
a space surrounded by a groove portion formed between adjacent protruding strip portions and the second member is a flow channel through which a refrigerant flows.

2. The base according to claim 1,
wherein the adhesive layer is formed only at a position in contact with the top surface of the protruding strip portion.

3. The base according to claim 1,
wherein a thickness of the adhesive layer is 30 μm or more and 300 μm or less.

4. The base according to claim 1,
wherein the adhesive layer is positioned below an upper end of the flow channel.

5. An electrostatic chuck device comprising:
an electrostatic chuck member made of a ceramic material;
the base according to claim 1; and
a bonding layer bonding the electrostatic chuck member to the base,
wherein the electrostatic chuck member contains 50% by volume or more of aluminum oxide in a case where a total amount of the electrostatic chuck member is taken as 100% by volume.

6. The electrostatic chuck device according to claim 5,
wherein the bonding layer contains a resin material and a thermally conductive filler, and
a content rate of the thermally conductive filler in the bonding layer is 50% by mass or more and 80% by mass or less.

7. A manufacturing method of a base comprising:
a step of forming a precursor in which a groove portion is formed on at least one of a pair of green sheets;
a step of infiltrating a metal into a sintered body obtained by calcining the precursor to manufacture a first member and a second member, the first member being made of a metal matrix composite and the second member being made of a metal matrix composite and overlapping with the first member; and
a step of disposing the first member and the second member to face each other with the groove portion facing inward and adhering the first member and the second member to each other with an organic sheet adhesive.
